(19) United States
(12) Patent Application Publication
(10) Pub. No.: US 2026/0032943 A1
(43) Pub. Date: Jan. 29, 2026

(54) SEMICONDUCTOR DEVICES INCLUDING A MASK PATTERN

(71) Applicant: Samsung Electronics Co., Ltd., Suwon-si (KR)

(72) Inventors: DONGHOON HWANG, Suwon-si (KR); HYOJIN KIM, Suwon-si (KR); BYUNGHO MOON, Suwon-si (KR); MINWOO KIM, Suwon-si (KR); JAEHO JEON, Suwon-si (KR)

(21) Appl. No.: 19/097,009

(22) Filed: Apr. 1, 2025

(30) Foreign Application Priority Data
Jul. 23, 2024 (KR) 10-2024-0096893

(51) Int. Cl. H10D 30/00; H10D 30/01

(52) U.S. Cl. CPC H10D 30/508; H10D 30/0196

(57) ABSTRACT

The semiconductor device includes active patterns on a substrate, each of the active patterns extending in a first direction, and an isolation pattern is on at least a portion of respective sidewalls of each of the active patterns, a gate structure on the active patterns and on the isolation pattern, the gate structure extending in a second direction substantially parallel to the upper surface of the substrate and intersecting the first direction, a mask pattern on the gate structure, a sidewall of the mask pattern is aligned with a sidewall of the gate structure, and a division pattern on the isolation pattern, the division pattern in contact with the sidewall of the gate structure and the sidewall of the mask pattern.

### CROSS-REFERENCE TO RELATED APPLICATION

This application claims priority under 35 U.S.C. § 119 to Korean Patent Application No. 10-2024-0096893 filed on Jul. 23, 2023 in the Korean Intellectual Property Office, the disclosure of which is hereby incorporated by reference in its entirety.

### FIELD

Example embodiments of the present disclosure relate to a semiconductor device.

### BACKGROUND OF THE INVENTION

As an integration degree of a semiconductor device increases, an electrical short and interference between conductive structures in the semiconductor device are becoming more severe. Thus, methods of reducing the electrical short and interference have been developed.

### SUMMARY OF THE INVENTION

Example embodiments provide a semiconductor device having improved characteristics.

According to example embodiments, there is provide a semiconductor device. The semiconductor device may include active patterns on a substrate, each of the active patterns extending in a first direction substantially parallel to an upper surface of the substrate, and an isolation pattern is on at least a portion of respective sidewalls of each of the active patterns, a gate structure on the active patterns and on the isolation pattern, the gate structure extending in a second direction substantially parallel to the upper surface of the substrate and intersecting the first direction, a mask pattern on the gate structure, a sidewall of the mask pattern is aligned with a sidewall of the gate structure, and a division pattern on the isolation pattern, the division pattern in contact with the sidewall of the gate structure and the sidewall of the mask pattern.

According to example embodiments, there is provide a semiconductor device. The semiconductor device may include active patterns on a substrate, each of the active patterns extending in a first direction substantially parallel to an upper surface of the substrate, and an isolation pattern on at least a portion of respective sidewalls of each of the active patterns, a gate structure on the active patterns and on the isolation pattern, the gate structure extending in a second direction substantially parallel to the upper surface of the substrate and intersecting the first direction, a division pattern including: a lower portion that extends beyond an end portion of the gate structure in a third direction perpendicular to the upper surface of the substrate, and an upper portion on the lower portion and in contact with the lower portion, the upper portion having a width in the second direction greater than a width in the second direction of the lower portion, and a mask pattern on the gate structure, the mask pattern in contact with a sidewall of the upper portion of the division pattern, wherein a lower surface of the upper portion of the division pattern has a length substantially the same as a length of a lower surface of the mask pattern with respect to the substrate.

According to example embodiments, there is provide a semiconductor device. The semiconductor device may include active patterns on a substrate, each of the active patterns extending in a first direction substantially parallel to an upper surface of the substrate, and an isolation pattern is on at least a portion of respective sidewalls of each of the active patterns, a gate structure on the active patterns and on the isolation pattern, the gate structure extending in a second direction substantially parallel to the upper surface of the substrate and intersecting the first direction, a plurality of channels spaced apart from each other on the substrate in a third direction substantially perpendicular to the upper surface of the substrate, each of the plurality of channels extending in the first direction, a mask pattern on a portion of an upper surface of the gate structure, a division pattern on the isolation pattern and extending into the gate structure and the mask pattern, the division pattern in contact with a sidewall of the mask pattern and a sidewall of the gate structure, a source/drain layer on each of the active patterns, and first and second contact plugs on the source/drain layer and the gate structure, respectively, wherein the sidewall of the mask pattern and the sidewall of the gate structure align with each other.

In the semiconductor device in accordance with example embodiments, the division pattern for dividing the gate structure may be easily formed. Thus, the distance between active patterns, which is needed for forming the division pattern, may be minimized, and the integration degree of the semiconductor device may be improved.

### BRIEF DESCRIPTION OF THE DRAWINGS

FIGS. 1 to 4 are a plan view and cross-sectional views illustrating a semiconductor device in accordance with example embodiments.

FIGS. 5 to 27 are plan views and cross-sectional views illustrating a method of manufacturing a semiconductor device in accordance with example embodiments.

FIG. 28 is a cross-sectional view illustrating a semiconductor device in accordance with example embodiments.

FIGS. 29 and 30 are cross-sectional views illustrating a method of manufacturing a semiconductor device in accordance with example embodiments.

### DETAILED DESCRIPTION

The above and other aspects and features of a semiconductor device and a method of manufacturing the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, two directions that are substantially perpendicular to each other among horizontal directions, which are substantially parallel to an upper surface of each of first to third substrates, may be referred to as first and second directions D1 and D2, respectively, and a vertical direction substantially perpendicular to the upper surface of the each of first to third substrates may be referred to as a third direction D3. In example embodiments, the first and second directions D1 and D2 may be orthogonal to each other. Each of the first to third directions D1, D2 and D3 may represent not only a direction shown in the drawing, but also a reverse direction to the direction.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device.

The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

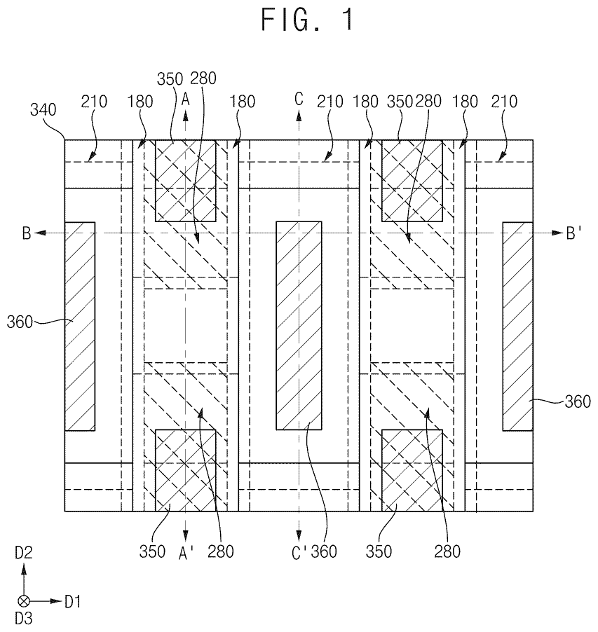

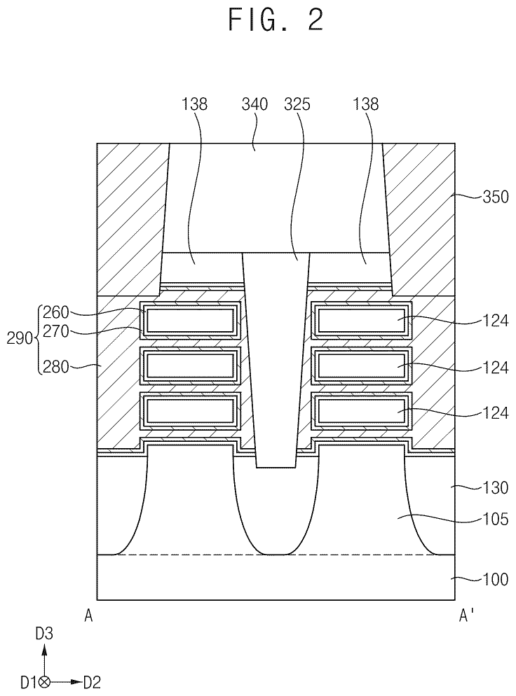

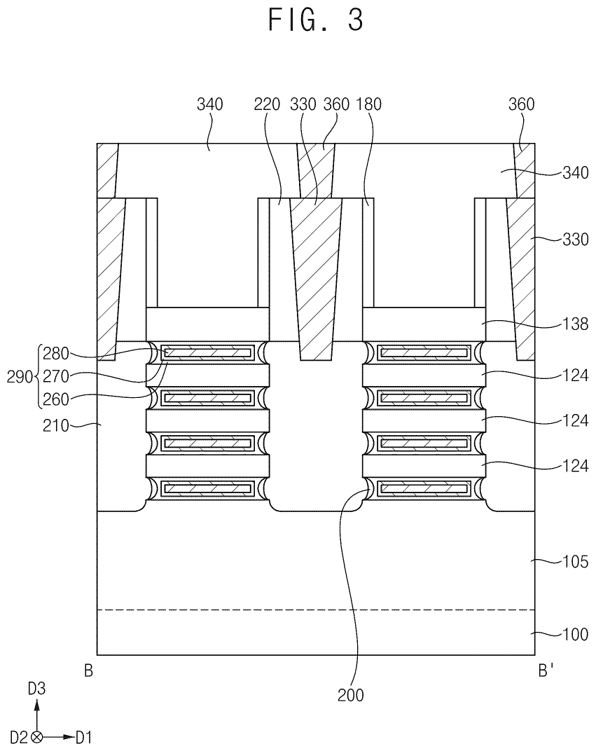

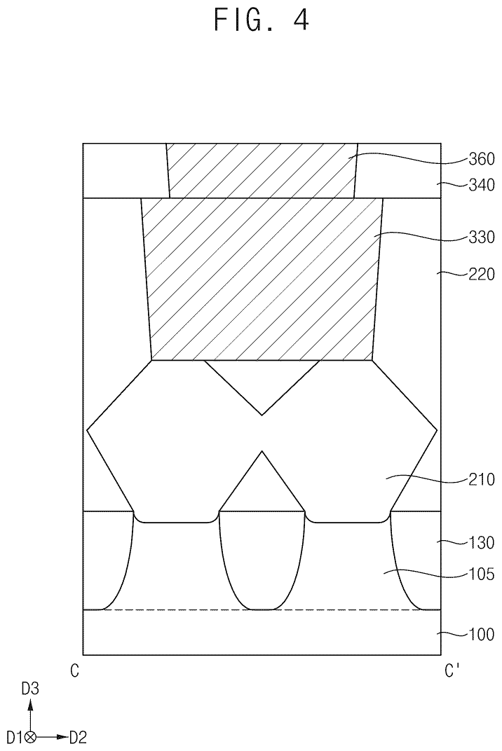

FIGS. 1 to 4 are a plan view and cross-sectional views illustrating a semiconductor device in accordance with example embodiments. Specifically, FIG. 1 is the plan view, and FIGS. 2 to 4 are the cross-sectional views. FIG. 2 is a cross-sectional view taken along line A-A′ of FIG. 1, FIG. 3 is a cross-sectional view taken along line B-B′ of FIG. 1, and FIG. 4 is a cross-sectional view taken along line C-C′ of FIG. 1.

Referring to FIGS. 1 to 4, the semiconductor device may include an active pattern 105, an isolation pattern 130, semiconductor patterns 124, a gate structure 290, a first spacer 180, a source/drain layer 210, a second spacer 200, a mask pattern 138, a first division pattern 325, first and second contact plugs 330 and 350, first and second insulating interlayers 220 and 340 and a via 400 on a substrate 100.

The substrate 100 may include a semiconductor material, e.g., silicon, germanium, silicon-germanium, etc., or III-V semiconductor compounds, e.g., GaP, GaAs, GaSb, etc. In some embodiments, the substrate 100 may include a silicon-on-insulator (SOI) substrate or a germanium-on-insulator (GOI) substrate.

In example embodiments, the active pattern 105 may extend in the first direction D1, and a plurality of active patterns 105 may be spaced apart from each other in the second direction D2.

In example embodiments, the isolation pattern 130 may extend in the first direction D1 between neighboring ones of the two active patterns 105, and a plurality of isolation patterns 130 may be spaced apart from each other in the second direction D2.

The active pattern 105 may include a material substantially the same as that of the substrate 100, and the isolation pattern 130 may include an oxide, e.g., silicon oxide.

In example embodiments, a plurality of semiconductor patterns 124 may be formed at a plurality of levels, respectively, and may be spaced apart from each other in the third direction D3 from an upper surface of the active pattern 105. Each of the plurality of semiconductor patterns 124 may extend in the first direction D1. FIGS. 2 and 3 show three semiconductor patterns 124 at three levels, respectively, however, the inventive concept is not limited thereto.

Additionally, FIG. 3 shows two semiconductor patterns 124 spaced apart from each other in the first direction D1 at each level over the active pattern 105 extending in the first direction D1, however, the inventive concept is not limited thereto.

In example embodiments, the semiconductor pattern 124 may be a nano-sheet or nano-wire including a semiconductor material, e.g., silicon, germanium, etc. In example embodiments, the semiconductor pattern 124 may serve as a channel in a transistor, and thus may also be referred to as a channel.

The gate structure 290 may extend in the second direction D2 on the active pattern 105 and the isolation pattern 130, and may include a gate insulation pattern 260, a gate barrier pattern 270 and a gate electrode 280.

In example embodiments, the gate structure 290 may surround a central portion in the first direction D1 of each of the semiconductor patterns 124 and may cover lower and upper surfaces and opposite sidewalls in the second direction D2 of each of the semiconductor patterns 124.

In example embodiments, the gate insulation pattern 260 may be disposed on a surface of each of the semiconductor patterns 124, a lower surface of the mask pattern 138, and upper surfaces of the active pattern 105 and the isolation pattern 130. The gate barrier pattern 270 may be disposed on a surface of the gate insulation pattern 260. The gate electrode 280 may fill a space between the semiconductor patterns 124 spaced apart from each other in the third direction D3, and a space between the active pattern 105 and a lowermost one of the semiconductor pattern 124.

The gate insulation pattern 260 may include an oxide, e.g., silicon oxide or a high-k dielectric material, e.g., hafnium oxide (HfO₂). The gate barrier pattern 270 may include a metal nitride, e.g., titanium nitride (TiN). The gate electrode 280 may include a metal nitride, e.g., titanium nitride (TiN), titanium aluminum nitride (TiAlN), tantalum nitride (TaN), tantalum aluminum nitride (TaAlN), etc., a metal alloy, a metal carbide, a metal oxynitride, a metal carbonitride or a metal oxycarbonitride, e.g., titanium aluminum carbide (TiAlC), titanium aluminum oxynitride (TiAlON), titanium aluminum carbonitride (TiAlCN), titanium aluminum oxycarbonitride (TiAlOCN), etc., or a low-resistance metal, e.g., tungsten (W), aluminum (Al), copper (Cu), or tantalum (Ta).

The second spacer 200 may be disposed between the semiconductor patterns 124 and may cover each of opposite sidewalls of the gate structure 290 in the first direction D1. In an embodiment, the second spacer 200 may have a cross-section taken along the first direction D1, which may have a horseshoe-shape or a semicircle shape with a recess on a side thereof. The second spacer 200 may include an insulating nitride, e.g., silicon nitride.

The source/drain layer 210 may be disposed on a portion of the active pattern 105 adjacent to the gate structure 290 and may commonly contact sidewalls of the semiconductor patterns 124 at the plurality of levels, respectively, to be electrically connected thereto.

In example embodiments, each of opposite sidewalls of the source/drain layer 210 in the first direction D1 may contact the sidewalls of the semiconductor patterns 124 and the sidewalls of the second spacers 200. As the second spacer 200 has a convex shape toward the gate structure 290, each of the sidewalls of the source/drain layer 210 in the first direction D1 may have a protrusion that protrudes toward the gate structure 290, correspondingly.

That is, a portion of the gate structure 290 between the semiconductor patterns 124 spaced apart from each other in the third direction D3 may have a width in the first direction D1 smaller than a width in the first direction D1 of the semiconductor patterns 124, and a sidewall in the first direction D1 of the portion of the gate structure 290 may have a concave shape compared to the sidewall in the first direction D1 of the semiconductor patterns 124, which may be disposed above and below thereof, respectively.

In example embodiments, the source/drain layer 210 may have a cross-section taken along the second direction D2, which may have a pentagon-like shape. In this case, the source/drain layer 210 may include single crystalline silicon-germanium doped with p-type impurities and may serve as a source/drain layer of a PMOS transistor.

In other embodiments, the source/drain layer 210 may have a cross-section taken along the second direction D2, which may have a square with rounded corners or a circle shape. In this case, the source/drain layer 210 may include silicon doped with n-type impurities or silicon carbide doped with n-type impurities and may serve as a source/drain layer of an NMOS transistor.

The mask pattern 138 may be disposed on the gate structure 290 and may have a lower surface contacting the upper surface of the gate structure 290. An end portion in the second direction D2 of the lower surface of the mask pattern 138 may be aligned with an end portion in the second direction D2 of the gate structure 290 in the third direction D3.

In example embodiments, the mask pattern 138 may have a width in the second direction D2 that is greater than a width of the semiconductor pattern 124 in the second direction D2, a width in the first direction D1 substantially the same as the width of the semiconductor pattern 124 in the first direction D1, and a thickness in the third direction D3 greater than a thickness of the semiconductor pattern 124 in the third direction D3.

In example embodiments, a height in the third direction D3 of the lower surface of the mask pattern 138 may be substantially the same as a height in the third direction D3 of an upper surface of the source/drain layer 210. In another embodiment, the height in the third direction D3 of the lower surface of the mask pattern 138 may be lower than the height in the third direction D3 of the upper surface of the source/drain layer 210. In this case, the mask pattern 138 may contact a sidewall of the source/drain layer 210 in the first direction D1.

In an embodiment, a distance in the third direction D3 between the mask pattern 138 and an uppermost one of the semiconductor patterns 124 may be greater than a distance between neighboring ones of the semiconductor patterns 124 in the third direction D3. Thus, a thickness of the gate structure 290 on the uppermost one of the semiconductor patterns 124 in the third direction D3 may be greater than a thickness in the third direction D3 of a portion of the gate structure 290 between the semiconductor patterns 124 disposed below the uppermost one of the semiconductor patterns 124 and a thickness in the third direction D3 of a portion of the gate structure 290 below the lowermost one of the semiconductor patterns 124.

In another embodiment, the distance between the mask pattern 138 and the uppermost one of the semiconductor patterns 124 in the third direction D3 may be substantially the same as the distance between the neighboring ones of the semiconductor patterns 124 in the third direction D3. Thus, the thickness in the third direction D3 of the portion of the gate structure 290 on the uppermost one of the semiconductor patterns 124, the thickness of the portion of the gate structure 290 between the semiconductor patterns 124 disposed below the uppermost one of the semiconductor patterns 124 and the thickness in the third direction D3 of the portion of the gate structure 290 below the lowermost one of the semiconductor patterns 124 may be substantially the same.

In example embodiment, the mask pattern 138 may include an insulating material, e.g., silicon nitride.

The first division pattern 325 may be disposed between ones of the gate structures 290, each of which may extend in the second direction D2, neighboring in the second direction D2. An upper portion of each of opposite sidewalls in the second direction D2 of the first division pattern 325 may contact a sidewall of the mask pattern 138 in the second direction D2, and a lower portion of each of opposite sidewalls in the second direction D2 of the first division pattern 325 may contact a sidewall of the gate electrode 280 in the second direction D2. That is, the first division pattern 325 may contact the end portion of the gate structure 290 in the second direction D2 and the end portion of the mask pattern 138 in the second direction D2.

In example embodiment, a height in the third direction D3 of an upper surface of the first division pattern 325 may be substantially the same as a height in the third direction D3 of an upper surface of the mask pattern 138. A lower surface of the first division pattern 325 may be lower than the upper surface of the first division pattern 325.

The first spacer 180 may be disposed on each of opposite sides in the first direction D1 of a portion of the second insulating interlayer 340 on each of the gate structure 290 and the mask pattern 138, and an outer sidewall of the first spacer 180 in the first direction D1 may be aligned in the third direction D3 with an outer sidewall of the mask pattern 138 in the first direction D1. The first spacer 180 may include an oxide, e.g., silicon oxide, or an insulating nitride, e.g., silicon nitride.

The first insulating interlayer 220 may be disposed on the isolation pattern 130 and may cover the upper surface of the source/drain layer 210, the opposite sidewalls of the mask pattern 138 in the first direction D1 and the outer sidewall of the first spacer 180 in the first direction D1. The second insulating interlayer 340 may be disposed on the mask pattern 138, the gate structure 290, the first division pattern 325, the first spacer 180 and the first insulating interlayer 220.

Each of the first and second insulating interlayers 220 and 340 may include insulating materials, e.g., silicon oxycarbide (SiOC), silicon oxide (SiO₂), silicon nitride (SiN), silicon oxynitride (SiON), silicon carbonitride (SiCN), silicon oxycarbonitride (SiOCN), etc.

The first contact plug 330 may extend through the first insulating interlayer 220 and contact the upper surface of the source/drain layer 210, the second contact plug 350 may extend through the second insulating interlayer 340 and the mask pattern 138 and contact an upper surface of the gate electrode 280, and the via 360 may extend through the second insulating interlayer 340 and contact an upper surface of the first contact plug 330. Each of the first and second contact plugs 330 and 350 and the via 360 may include, e.g., metal and/or metal nitride.

The semiconductor device may be a multi-bridge channel field effect transistor (MBCFET) including semiconductor patterns 124, which may be spaced apart from each other in the third direction D3 and serve as channels, respectively.

As illustrated above, the semiconductor device may include the first division pattern 325 dividing the gate structure 290 extending in the second direction D2. As illustrated below, during an etching process for forming an opening, in which the first division pattern 325 may be formed, the mask pattern 138 on the semiconductor patterns 124 may be used as an etching mask, so that an additional patterning process may be skipped, and the first division pattern 325 may be formed after the gate structure 290 is formed. Thus, the gate barrier pattern 270 may not be formed on the sidewall of the first division pattern 325 so that the gate barrier pattern 270 may not contact the semiconductor patterns 124.

Accordingly, a distance between the active patterns 105, which is needed for forming the first division pattern 325, may be minimized, and the integration degree of the semiconductor device may be improved.

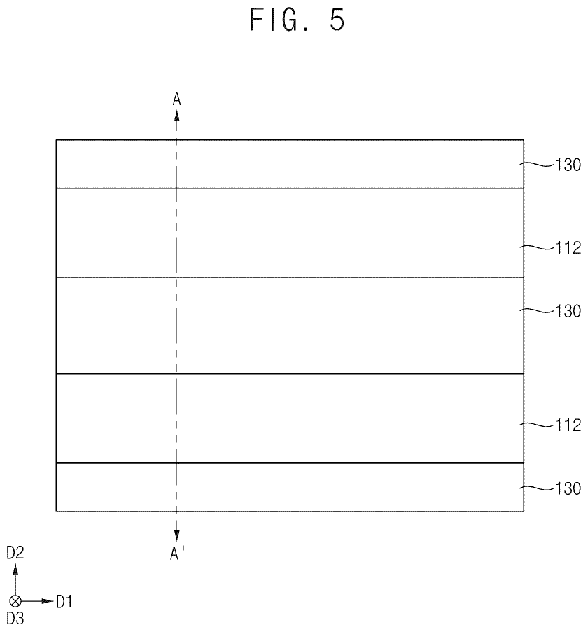

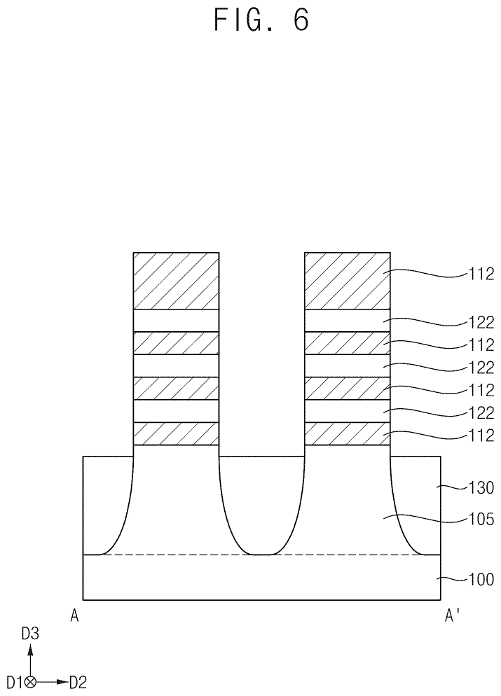

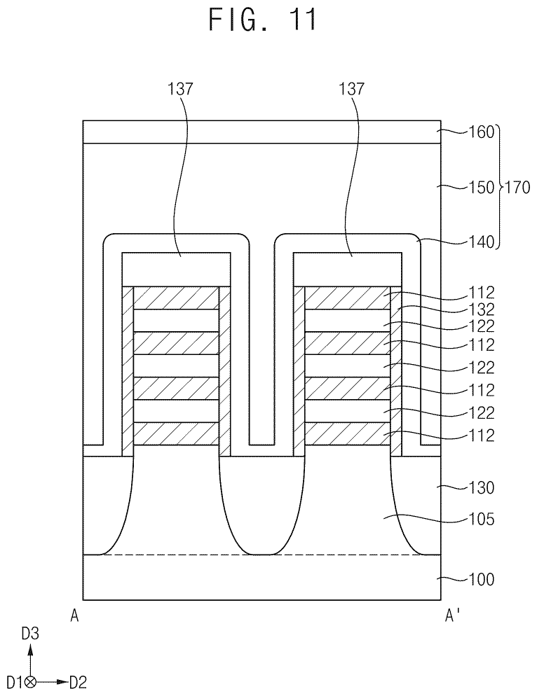

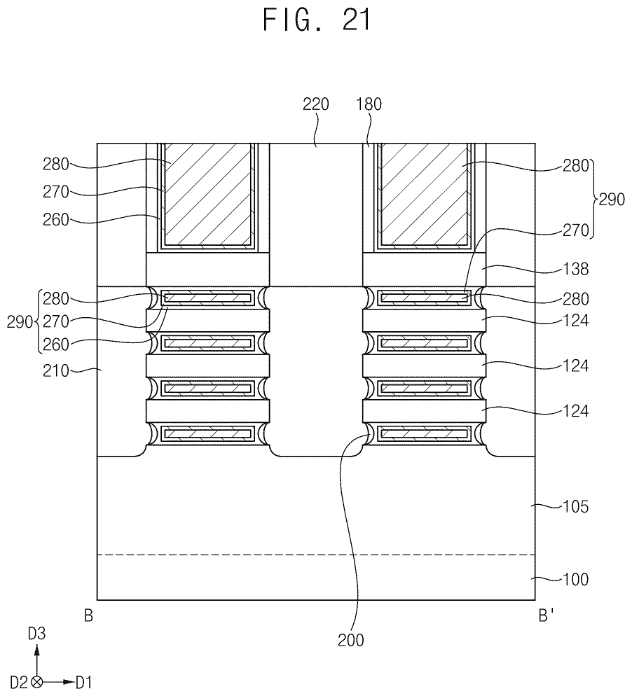

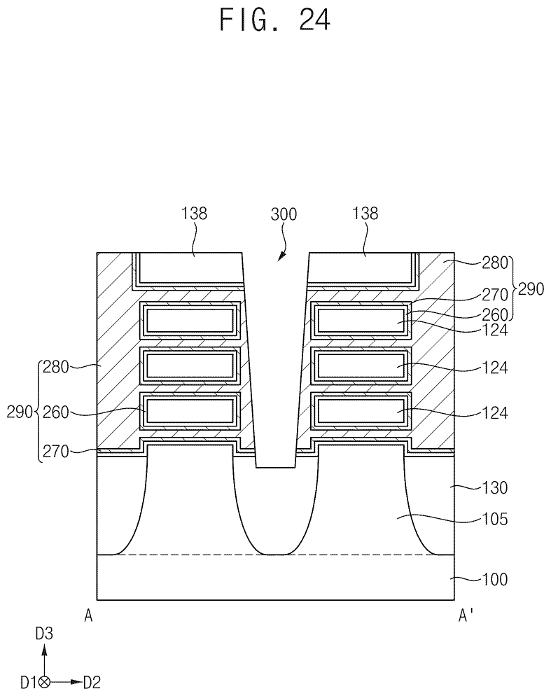

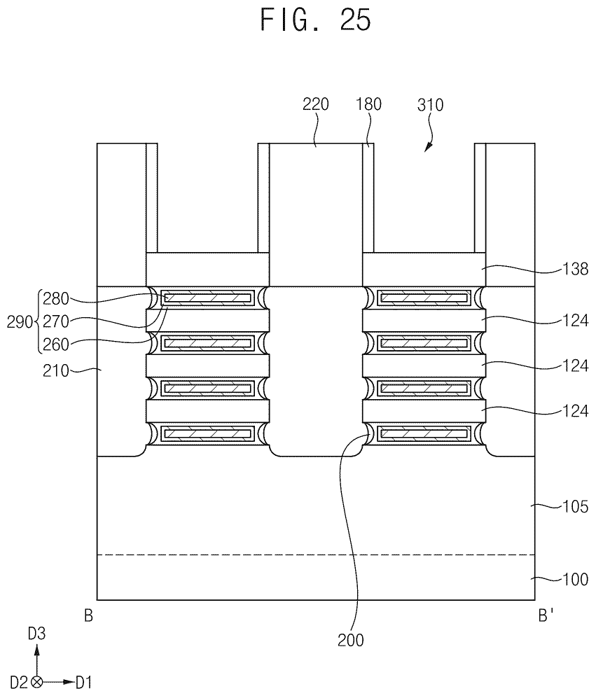

FIGS. 5 to 27 are plan views and cross-sectional views illustrating a method of manufacturing a semiconductor device in accordance with example embodiments. Particularly, FIGS. 5, 10 and 23 are the plan views, and FIGS. 6-9, 11-22 and 24-27 are the cross-sectional views.

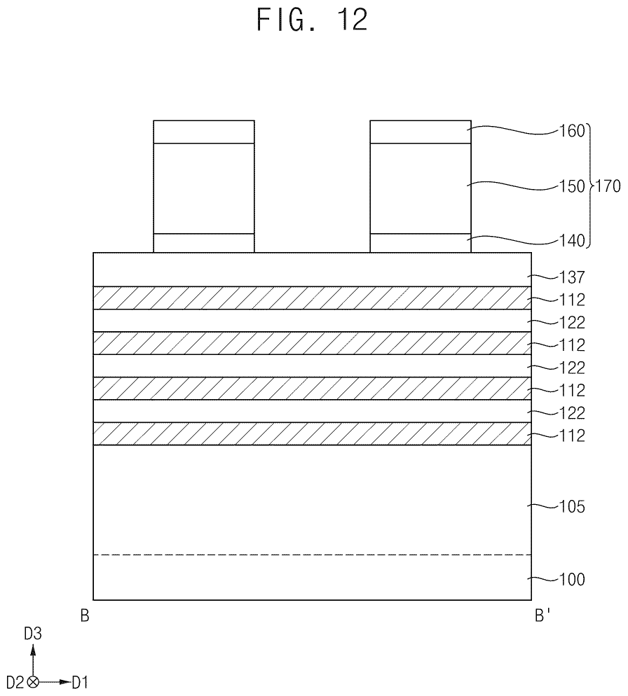

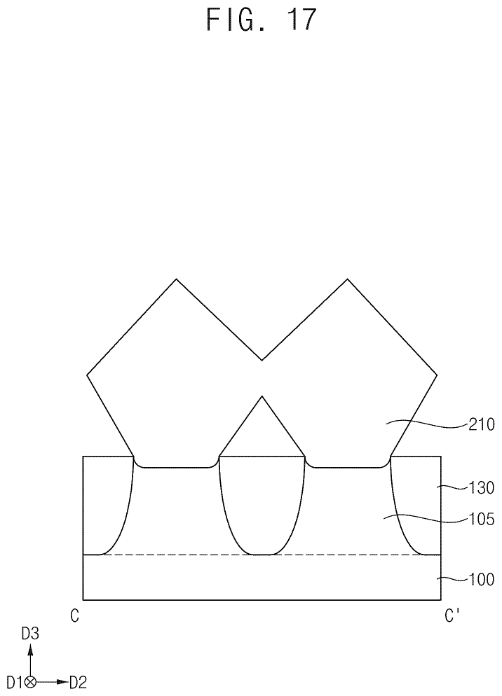

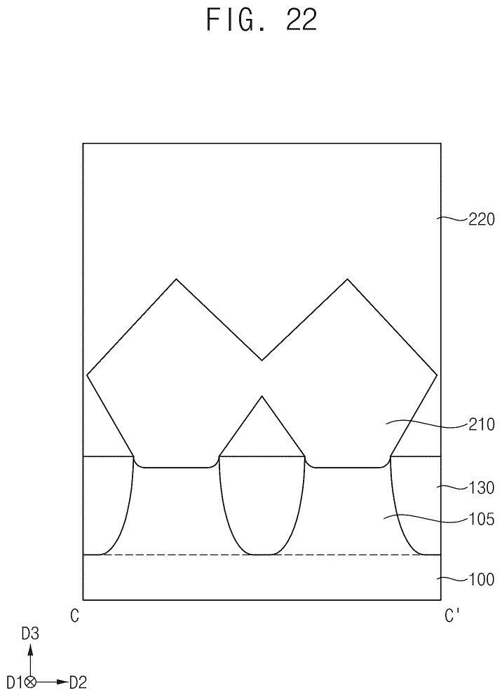

FIGS. 6-9, 11, 18, 20, 24 and 26 are cross-sectional views taken along lines A-A′ of corresponding plan views, respectively, FIGS. 12-16, 19, 21, 25 and 27 are cross-sectional views taken along lines B-B′ of corresponding plan views, respectively, and FIGS. 17 and 22 are cross-sectional views taken along line C-C′ of corresponding plan views.

Referring to FIGS. 5 and 6, a sacrificial layer and a semiconductor layer may be alternately and repeatedly stacked on a substrate 100, a first etching mask extending in the first direction D1 may be formed on an uppermost one of the semiconductor layers, and the semiconductor layers, the sacrificial layers, and an upper portion of the substrate 100 may be etched using the first etching mask.

Thus, an active pattern 105 extending in the first direction D1 may be formed on the substrate 100, and a first stack structure including sacrificial lines 112 and semiconductor lines 122 alternately and repeatedly stacked in the third direction D3 may be formed on the active pattern 105. In example embodiments, the first stack structure may extend in the first direction D1, and a plurality of first stack structures may be spaced apart from each other in the second direction D2 on the substrate 100.

FIG. 6 shows four sacrificial lines 112 and three semiconductor lines 122 at three levels, respectively, however, the inventive concept is not limited thereto. The semiconductor lines 122 may include, e.g., silicon, and the sacrificial lines 112 may include a material having an etching selectivity with respect to the substrate 100 and the semiconductor lines 122, e.g., silicon-germanium.

In example embodiments, an uppermost one of the sacrificial lines 112 may have a thickness in the third direction D3 greater than a thickness in the third direction D3 of each of the sacrificial lines 112 under the uppermost one of the sacrificial lines 112. In an embodiment, the thickness in the third direction D3 of the uppermost one of the sacrificial lines 112 may be substantially the same as the thickness in the third direction D3 of each of the sacrificial lines 112 under the uppermost one of the sacrificial lines 112. In another embodiments, the thickness in the third direction D3 of the uppermost one of the sacrificial lines 112 may be smaller than the thickness in the third direction D3 of each of the sacrificial lines 112 under the uppermost one of the sacrificial lines 112.

An isolation pattern 130 may be formed on the substrate 100 to cover a sidewall of the active pattern 105.

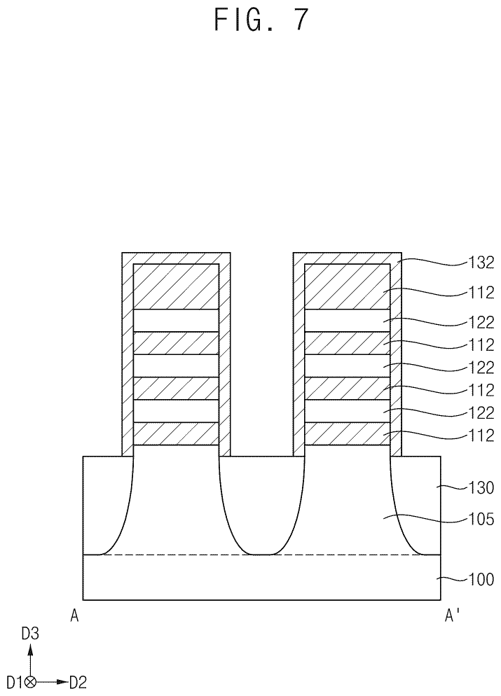

Referring to FIG. 7, for example, a first selective epitaxial growth (SEG) process may be performed on an upper surface and opposite sidewalls in the second direction D2 of the first stack structure to form a sacrificial structure 132.

In example embodiments, the first SEG process may be performed using sidewalls of the sacrificial lines 112, an upper surface of the uppermost one of the sacrificial lines 112, sidewalls of the semiconductor lines 122 and an upper sidewall of the active pattern 105 as seed layers.

In example embodiments, the sacrificial structure 132 may extend in the first direction D1 corresponding to the first stack structure, and a plurality of sacrificial structures 132 may be spaced apart from each other in the second direction D2. The sacrificial structure 132 may include a material substantially the same as the sacrificial line 112, e.g., silicon-germanium (SiGe).

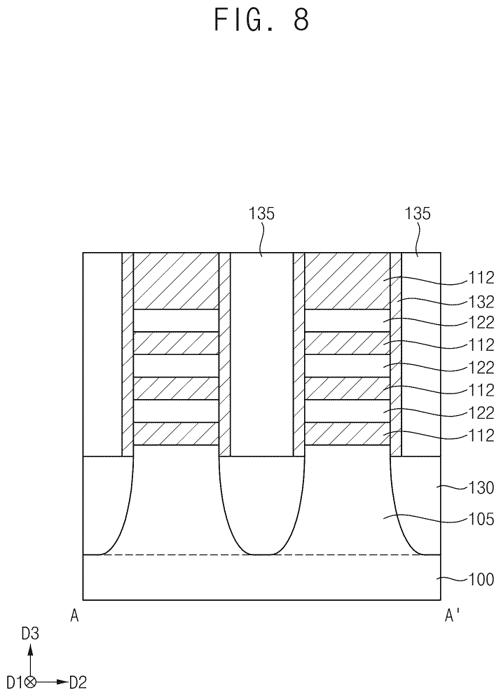

Referring to FIG. 8, an insulation layer may be formed on the isolation pattern 130 and the sacrificial structure 132, and for example, a chemical mechanical polishing (CMP) process may be performed on the insulation layer until the upper surface of the first stack structure is exposed to form a first insulation pattern 135.

In example embodiments, the first insulation pattern 135 may extend in the first direction D1, and a plurality of first insulation patterns 135 may be spaced apart from each other in the second direction D2. The first insulation pattern 135 may include, e.g., silicon oxide. During the CMP process, a portion of the sacrificial structure 132 on the upper surface of the first stack structure may also be removed, so that the sacrificial structure 132 may remain only on the opposite sidewalls of the first stack structure in the second direction D2.

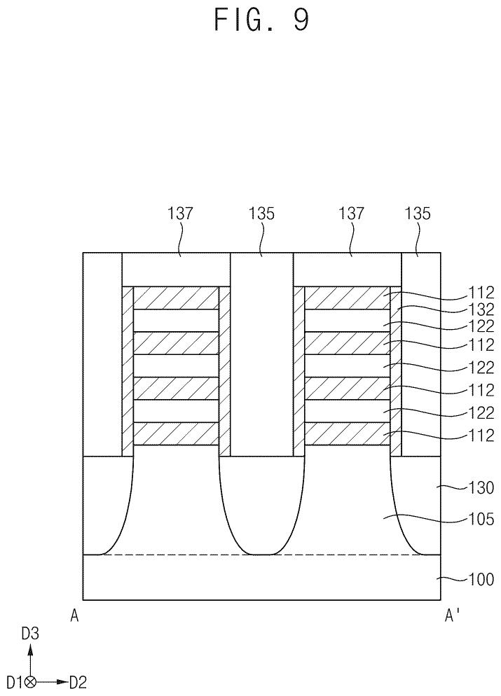

Referring to FIG. 9, a first recess may be formed by removing upper portions of the first stack structure and the sacrificial structure 132, a mask layer may be formed on the uppermost one of the sacrificial lines 112, the sacrificial structure 132 and the first insulating pattern 135 to fill the first recess, and a CMP process may be performed on the mask layer until an upper surface of the first insulation pattern 135 is exposed to form a mask line 137.

In example embodiments, the mask line 137 may extend in the first direction D1, and each of opposite sidewalls of the mask line 137 in the second direction D2 may be aligned in the third direction D3 with a corresponding one of opposite sidewalls of the sacrificial structure 132 in the second direction D2. Thus, the mask line 137 may have a width in the second direction D2 greater than a width in the second direction D2 of the semiconductor line 122 by a width in the second direction D2 of the sacrificial structure 132.

In an embodiment, a thickness in the third direction D3 of the uppermost one of the sacrificial lines 112 may be substantially the same as a thickness in the third direction D3 of each of ones of the sacrificial lines 112 that are disposed under the uppermost one of the sacrificial lines 112. In other embodiments, the thickness in the third direction D3 of the uppermost one of the sacrificial lines 112 may be greater than the thickness in the third direction D3 of each of ones of the sacrificial lines 112 that are disposed under the uppermost one of the sacrificial lines 112.

Hereinafter, the first stack structure, the sacrificial structure 132 remaining on the sidewall of the first stack structure, and the mask line 137 on the first stack structure and the sacrificial structure 132 may collectively be referred to as a second stack structure.

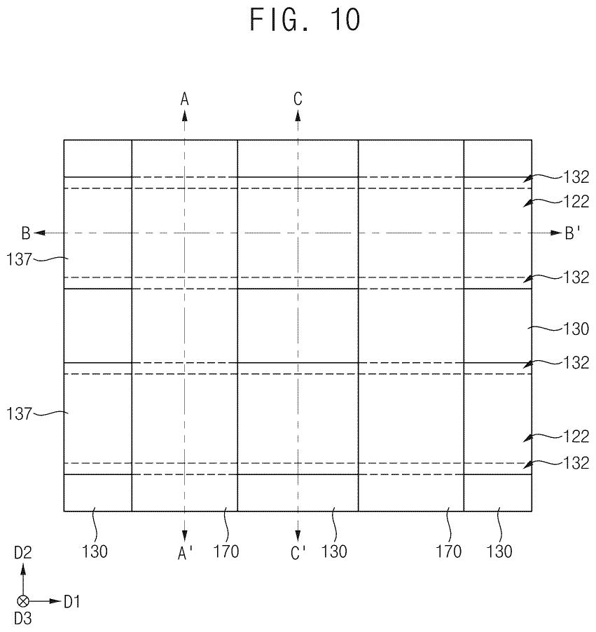

Referring to FIGS. 10 to 12, e.g., a dry etching process may be performed to remove the first insulation pattern 135, a dummy gate insulation layer, a dummy gate electrode layer and a dummy gate mask layer may be sequentially formed on the substrate 100 to cover the second stack structure and the isolation pattern 130, a second etching mask extending in the second direction D2 may be formed on the dummy gate mask layer, and the dummy gate mask layer may be etched using the second etching mask to form a dummy gate mask 160 on the substrate 100.

The dummy gate electrode layer and the dummy gate insulation layer may be etched using the dummy gate mask 160 as an etching mask to form a dummy gate electrode 150 and a dummy gate insulation pattern 140, respectively, on the substrate 100.

The dummy gate insulation pattern 140, the dummy gate electrode 150 and the dummy gate mask 160 sequentially stacked in the third direction D3 on the active pattern 105 and a portion of the isolation pattern 130 adjacent thereto may collectively form a dummy gate structure 170.

In example embodiments, the dummy gate structure 170 may extend in the second direction D2 on the second stack structure and the isolation pattern 130 and may cover an upper surface and opposite sidewalls in the second direction D2 of the second stack structure.

In example embodiments, a plurality of dummy gate structures 170 may be spaced apart from each other in the first direction D1.

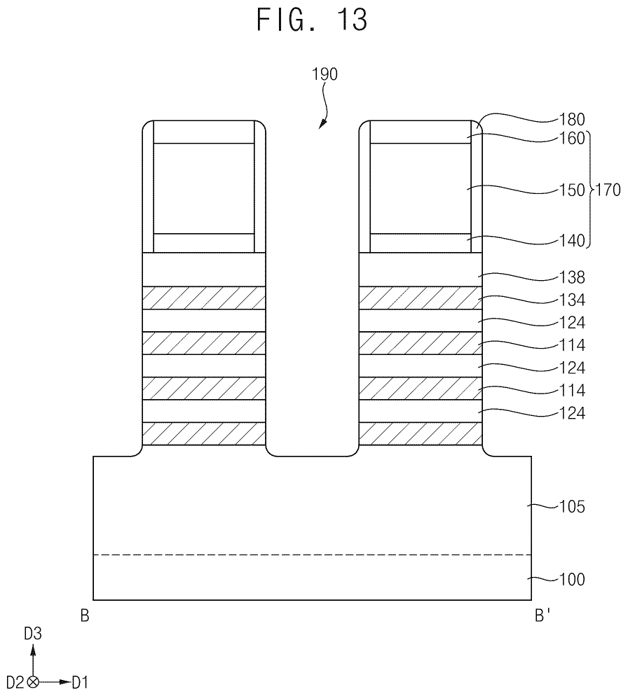

Referring to FIG. 13, a first spacer 180 may be formed on a sidewall of the dummy gate structure 170.

Particularly, a first spacer layer may be formed on the substrate 100 having the second stack structure, the isolation pattern 130 and the dummy gate structure 170 thereon and may be anisotropically etched to form the first spacer 180 covering each of opposite sidewalls in the first direction D1 of the dummy gate structure 170.

The second stack structure and an upper portion of the active pattern 105 may be etched using the dummy gate structure 170 and the first spacer 180 as an etching mask to form a first opening 190.

Thus, the mask line 137, the sacrificial lines 112 and the semiconductor lines 122 under the dummy gate structure 170 and the first spacer 180 may be transformed into a mask pattern 138, sacrificial patterns 114 and semiconductor patterns 124, respectively, and the second stack structure extending in the first direction D1 may be divided into a plurality of parts spaced apart from each other in the first direction D1.

Hereinafter, the dummy gate structure 170, the first spacer 180 on each of opposite sidewalls of the dummy gate structure 170 and the second stack structure may collectively be referred to as a third stack structure. In example embodiments, the third stack structure may extend in the second direction D2, and a plurality of third stack structures may be spaced apart from each other in the first direction D1.

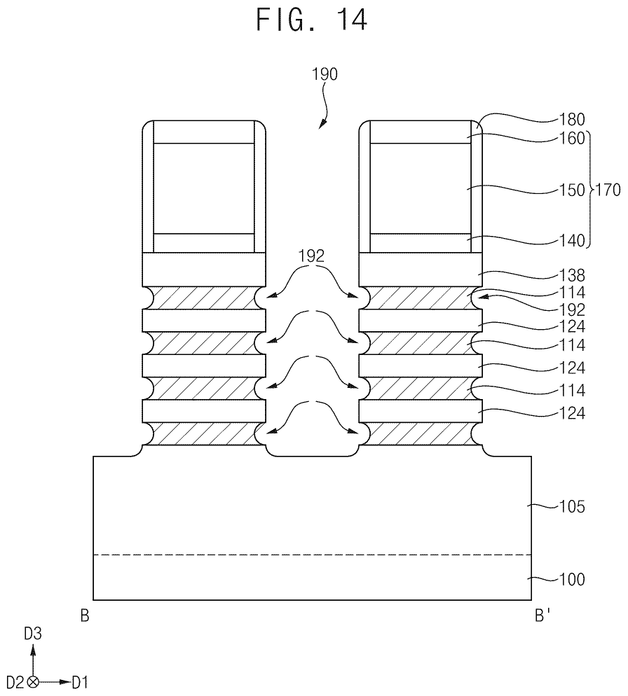

Referring to FIG. 14, each of the opposite sidewalls of the sacrificial patterns 114 exposed by the first opening 190 may be etched to form a second recess 192.

In example embodiments, the second recess 192 may be formed by performing, e.g., a wet etching process on the sacrificial patterns 114.

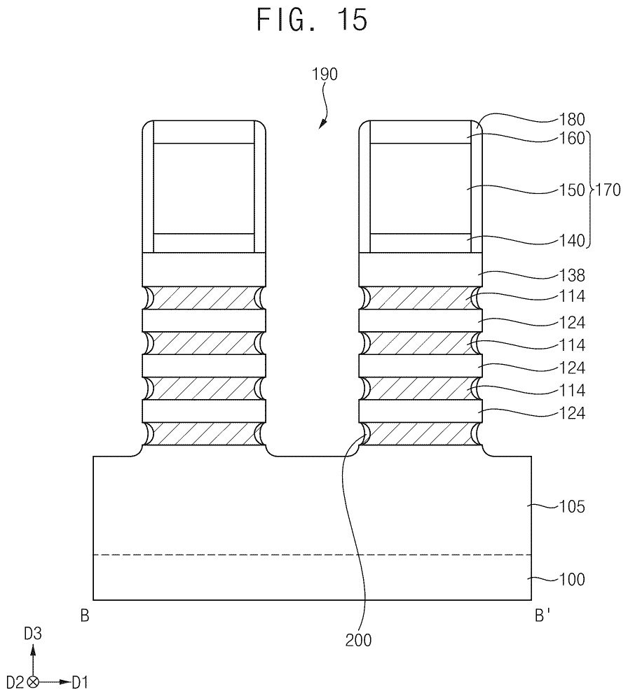

Referring to FIG. 15, a second spacer 200 may be formed in the second recess 192.

In example embodiments, the second spacer 200 may be formed by forming a second spacer layer on inner walls of the first opening 190 and the second recess 192, an upper surface of the active pattern 105 and an upper surface of the third stack structure, and anisotropically etching the second spacer layer.

Thus, the second spacer 200 may cover each of the opposite sidewalls of each of the sacrificial patterns 114 in the first direction D1. In an embodiment, the second spacer 200 may have a cross-section taken along the first direction D1 which may have a horseshoe shape or a semi-circular shape with a recess on a sidewall thereof.

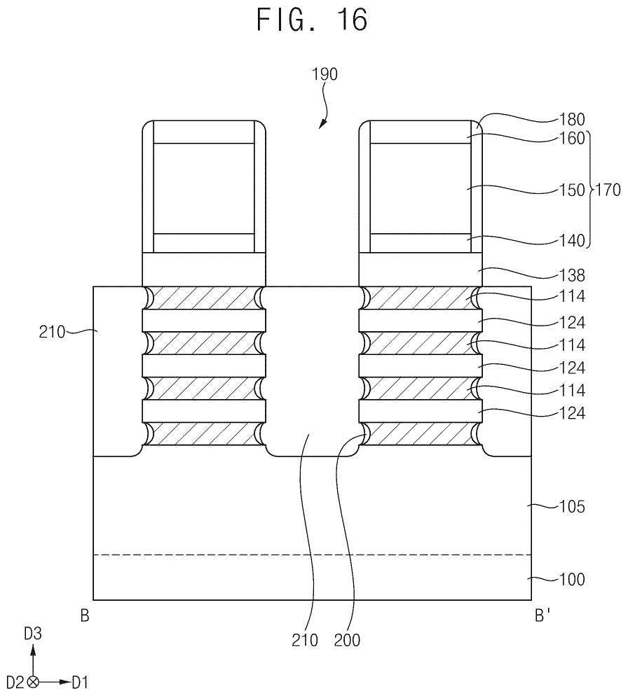

Referring to FIGS. 16 and 17, a second SEG process may be performed using the upper surface of the active pattern 105 and the sidewalls of the semiconductor patterns 124 and the sacrificial patterns 114 exposed by the first opening 190 as a seed to form a source/drain layer 210 in the first opening 190.

In some example embodiments, the second SEG process may be performed using a source gas, e.g., disilane (Si₂H₆) gas and SiH₃CH₃ gas, etc., and thus a single crystal silicon carbide (SiC) layer may be formed as the source/drain layer 210. In this case, n-type impurity source gas, e.g., PH₃, may also be used to form a single crystalline silicon carbide layer doped with n-type impurities. Alternatively, the SEG process may be performed using a silicon source gas, e.g., disilane (Si₂H₆) gas with the n-type impurity source gas, and in this case, a single crystalline silicon layer doped with n-type impurities may be formed as the source/drain layer 210.

In other embodiments, the SEG process may be performed using a silicon source gas, e.g., dichlorosilane (SiH₂Cl₂) gas, a germanium source gas, e.g., germane (GeH₄) gas, so that a single crystalline silicon-germanium layer may be formed as the source/drain layer 210. In this case, a p-type impurity source gas, e.g., diborane (B₂H₆) gas may also be used to form a single crystalline silicon-germanium layer doped with p-type impurities.

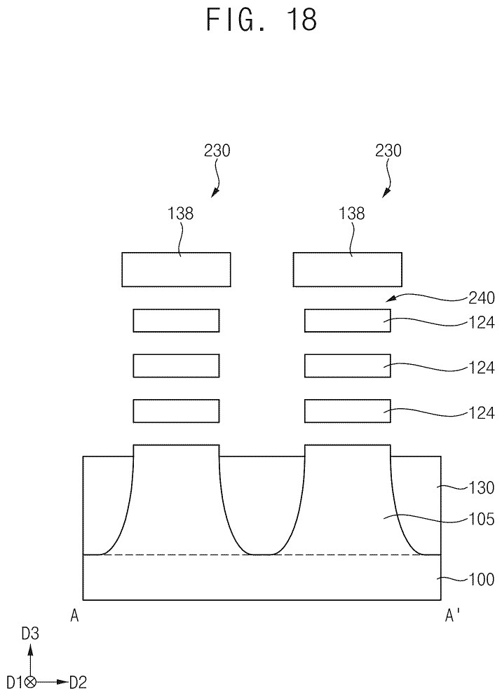

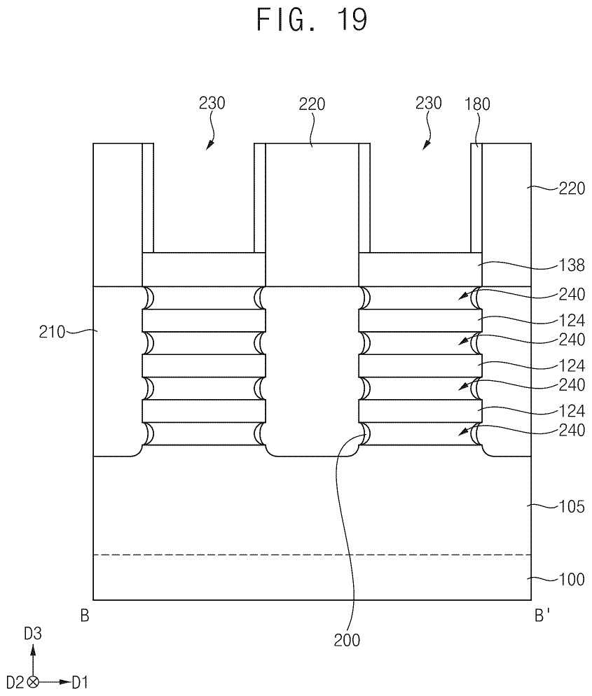

Referring to FIGS. 18 and 19, a first insulating interlayer 220 may be formed on the third stack structure, the source/drain layer 210 and the isolation pattern 130, a planarization process may be performed until an upper surface of the dummy gate electrode 150 included in the third stack structure is exposed to remove an upper portion of the first insulating interlayer 220 and the dummy gate mask 160 included in the dummy gate structure 170, and an upper portion of the first spacer 180 may also be removed.

The exposed dummy gate electrode 150 and the dummy gate insulation pattern 140, the sacrificial structure 132 and the sacrificial patterns 114 under the dummy gate electrode 150 may be removed by performing, e.g., a wet etching process and/or a dry etching process.

Thus, a second opening 230 exposing an inner sidewall of the first spacer 180 and an upper surface of the mask pattern 138 may be formed, and a third opening 240 exposing surfaces of the semiconductor patterns 124, the upper surface of the active pattern 105 and an inner sidewall of the second spacer 200 may be formed.

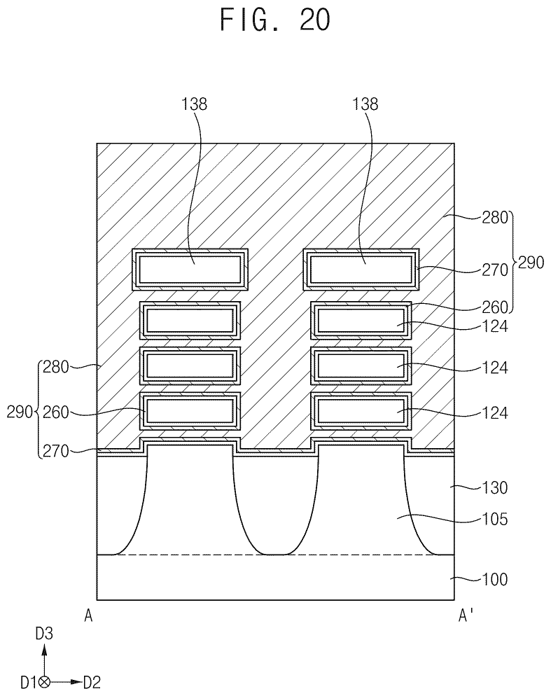

Referring to FIGS. 20 to 22, a gate insulation pattern 260 may be formed on the surfaces of the semiconductor patterns 124 and the upper surface of the active pattern 105 exposed by the second and third openings 230 and 240 by performing a thermal oxidation process, and a gate barrier layer and a gate electrode layer may sequentially be formed to fill the second and third openings 230 and 240 on the gate insulation pattern 260.

A planarization process may be performed on the gate barrier layer and gate electrode layer until an upper surface of the first insulating interlayer 220 is exposed, and thus, a gate insulation pattern 260, a gate barrier pattern 270 and a gate electrode 280 may be formed in the second and third openings 230 and 240.

The gate insulation pattern 260, the gate barrier pattern 270 and the gate electrode 280 may collectively form a gate structure 290.

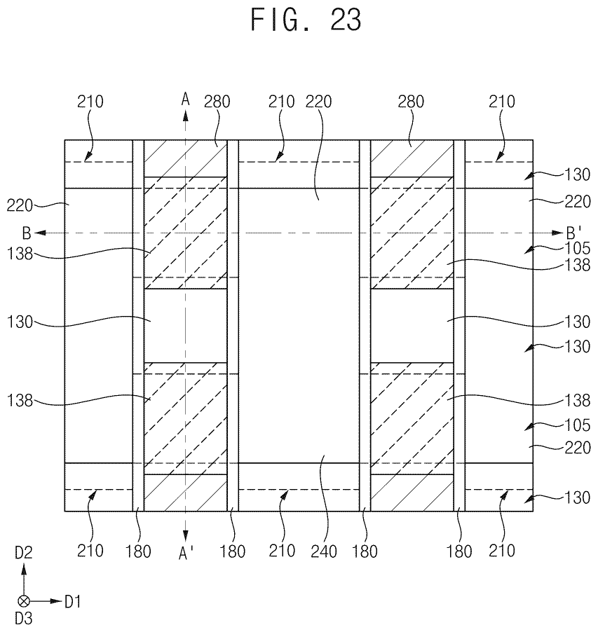

Referring to FIGS. 23 to 25, a first etching mask exposing the gate structure 290 may be formed on the first spacer 180 and the first insulating interlayer 220, and a dry etching process may be performed using the first etching mask.

The dry etching process may be performed until the upper surface of the mask pattern 138 is exposed, a portion of the gate structure 290 not covered by the mask pattern 138 may be removed to form a fourth opening 300 exposing an upper surface of the isolation pattern 130, and a portion of the gate structure 290, which is formed under the mask pattern 138 and covered by the mask pattern 138, may not be removed. A space between the first spacers 180 on the mask pattern 138 may be referred to as a fifth opening 310.

In example embodiments, the fourth opening 300 may expose a portion of the isolation pattern 130 between the active patterns 105 disposed in the second direction D2, and the fourth opening 300 may extend in the first direction D1 by at least a length substantially the same as or greater than a width of the gate structure 290 in the first direction D1. Thus, the gate structure 290 extending in the second direction D2 may be divided in second direction D2 into parts by the fourth opening 300.

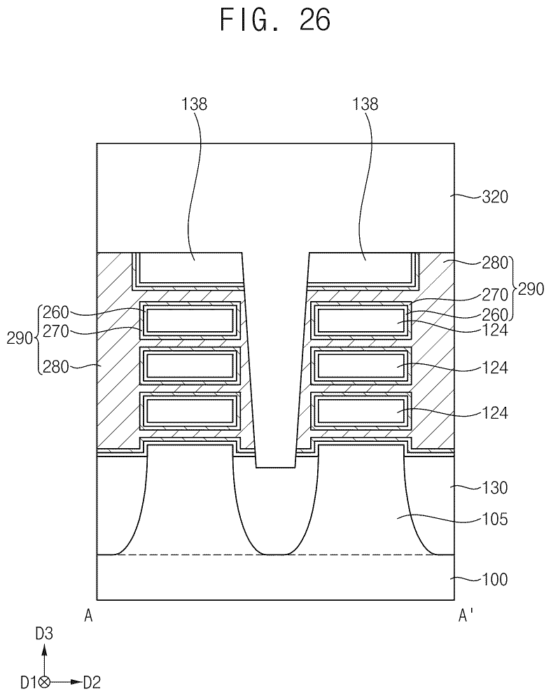

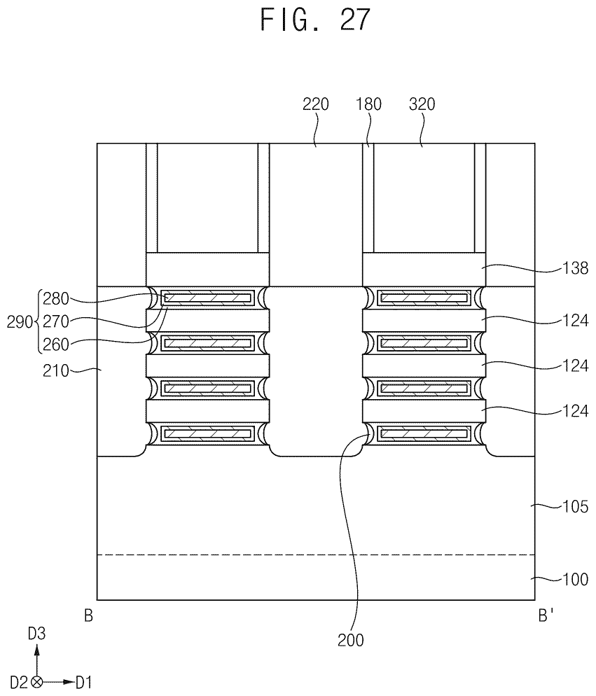

Referring to FIGS. 26 and 27, a second insulation layer may be formed on the first insulating interlayer 220, the first spacer 180, the gate structure 290, the mask pattern 138 and the isolation pattern 130 to fill the fourth and fifth openings 300 and 310 and, e.g., CMP process may be performed on the second insulation pattern until the upper surface of the first insulating interlayer 220 is exposed.

Referring back to FIGS. 1 to 4, a sixth opening exposing an upper portion of the source/drain layer 210 may be formed by partially removing the first insulating interlayer 220, and a first contact plug 330 may be formed to fill the sixth opening.

A first division pattern 325 may be formed by removing an upper portion of the second insulation pattern 320 until the upper surface of the mask pattern 138 is exposed.

A second insulating interlayer 340 may be formed on the first contact plug 330, the first insulating interlayer 220, the first spacer 180, the first division pattern 325 and the mask pattern 138, an etching process may be performed to partially remove the second insulating interlayer 340, the mask pattern 138 and the gate barrier pattern 270 to form a seventh opening exposing an upper surface of the gate electrode 280, and an eighth opening exposing an upper surface of the first contact plug 330 may be formed by partially removing the second insulating interlayer 340.

A second contact plug 350 and a via 360 may be formed to fill the seventh and eighth openings, respectively.

Upper wirings electrically connected to the second contact plug 350 and the via 360 may be formed, and by the above processes, the semiconductor device may be manufactured.

As illustrated above, the gate structure 290 extending in the second direction D2 may be divided into parts by the first division pattern 325. The first division pattern 325 may be formed by performing an etching process using the mask pattern 138 as an etching mask, which may be formed during the formation of the semiconductor patterns 124.

If, for example, the first division pattern 325 is formed by etching the dummy gate structure 170 extending in the second direction D2 to form an opening and filling the opening, during the process of replacing the dummy gate structure 170 with the gate structure 290, the gate barrier pattern 270 may be formed on the sidewall of the first division pattern 325 in the second direction D2. Thus, the gate barrier pattern 270 on the sidewall of the first division pattern 325 and the semiconductor pattern 124 may come into contact with each other, which may cause an electrical short or interference.

Alternatively, if, for example, the first division pattern 325 is formed by etching the gate electrode 280 to form an opening and filling the opening, the gate structure 290 may be damaged by the etching process for forming the opening, and as the integration degree of the semiconductor device increases, the distance between neighboring active patterns 105 decreases, so that the process of forming the opening between the active patterns 105 by the etching process may be difficult.

However, in example embodiments, the mask pattern 138 on the semiconductor patterns 124 may be used as an etching mask, so that an additional patterning process for forming the opening may be skipped, so that the difficulty of the process may decrease. Additionally, the first division pattern 325 may be formed after the forming the gate structure 290, and thus the gate barrier pattern 270 may not be formed on the sidewall of the first division pattern 325, so that an electrical short or interference between the gate barrier pattern 270 and the semiconductor pattern 124 may be prevented or reduced.

Thus, the distance between the active patterns 105, which is needed for forming the first division pattern 325, may be minimized, and ultimately, the integration degree of the semiconductor device may be improved.

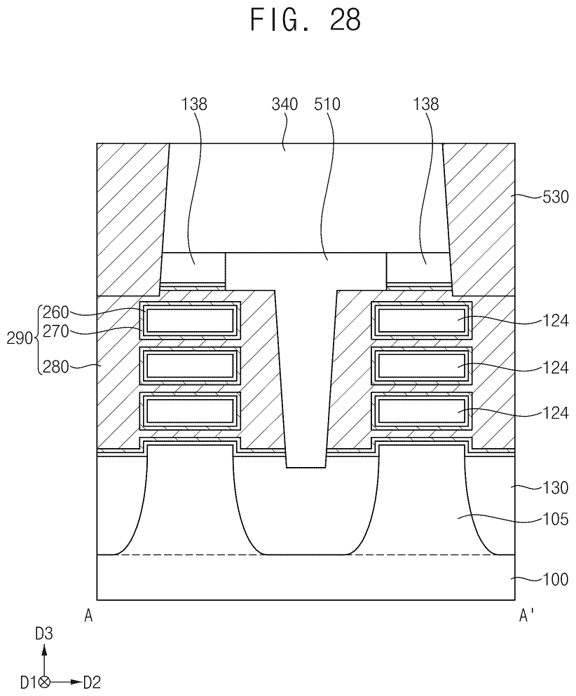

FIG. 28 is a cross-sectional view illustrating a semiconductor device in accordance with example embodiments, which corresponds to FIG. 2.

This semiconductor device may include elements substantially the same as or similar to those of the semiconductor device illustrated with reference to FIGS. 1 to 4 except for a second division pattern 510 instead of the first division pattern 325, and thus the same elements may be assigned the same reference numerals, and repeated explanation thereof are omitted herein.

Referring to FIG. 28, the second division pattern 510 may include a lower portion, which may contact an end portion of the gate structure 290 in the second direction D2, and an upper portion, which may be formed on and contact the lower portion and have a width in the second direction D2 greater than a width of the lower portion in the second direction D2.

In example embodiments, a lower surface of the upper portion of the second division pattern 510 may contact the gate barrier pattern 270, and a sidewall in the second direction D2 of the upper portion of the second division pattern 510 may contact a sidewall of the mask pattern 138 in the second direction D2. A sidewall of the lower portion of the second division pattern 510 in the second direction D2 may contact the gate barrier pattern 270 and the gate electrode 280.

In example embodiments, the lower portion of the second division pattern 510 may have a lower surface lower than an upper surface of the isolation pattern 130.

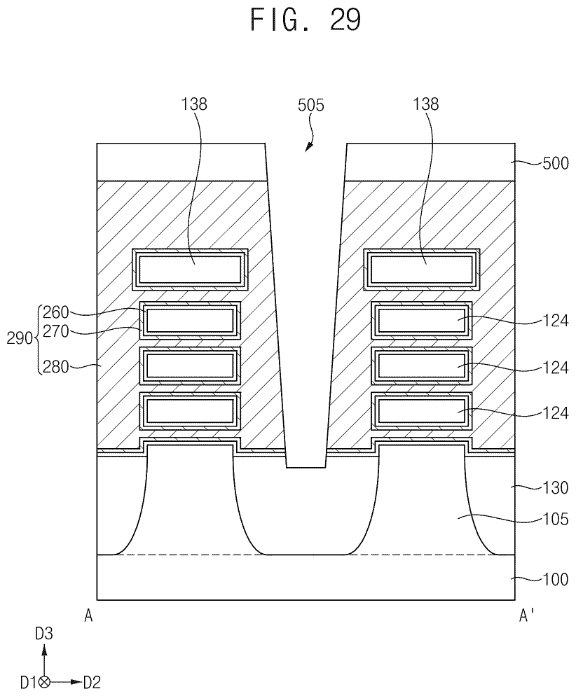

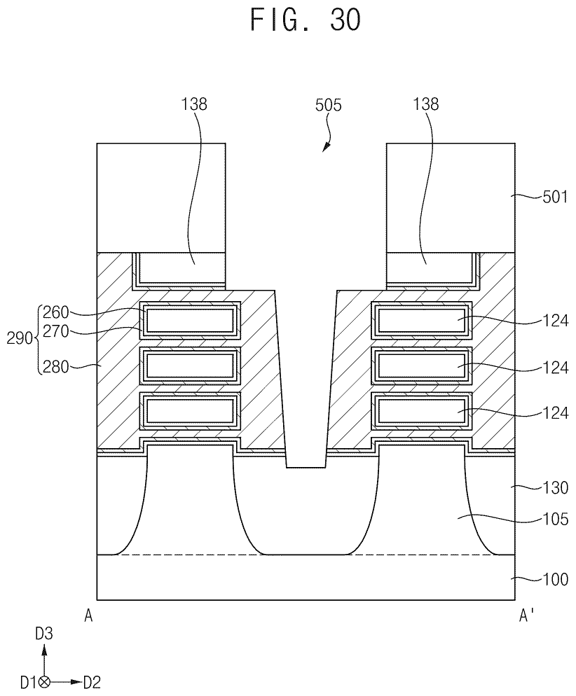

FIGS. 29 and 30 are cross-sectional views, respectively, illustrating a method of manufacturing a semiconductor device in accordance with example embodiments.

This method may include processes substantially the same as or similar to those illustrated with reference to FIGS. 5 to 27 and FIGS. 1 to 4, and thus repeated explanations thereof are omitted herein.

Referring to FIG. 29, processes substantially the same as or similar to the processes illustrated with reference to FIGS. 5 to 22 may be performed, a second etching mask 500 may be formed on the gate structure 290, the first spacer 180 and the first insulating interlayer 220 to expose a portion of the gate structure 290, a dry etching process may be performed on the gate structure 290 using the second etching mask, and thus a ninth opening 505 exposing an upper surface of the isolation pattern 130 may be formed.

Referring to FIG. 30, the second etching mask 500 may be removed, a third etching mask may be formed on the first spacer 180 and the first insulating interlayer 220 to expose the gate structure 290, and a dry etching process may be performed on the gate structure 290 using the third etching mask to remove an upper portion of the gate structure 290.

The dry etching process may be performed until an upper surface of the mask pattern 138 is exposed.

The third etching mask may be removed, a fourth etching mask 501 may be formed on the gate structure 290, the first spacer 180 and the first insulating interlayer 220 to expose a portion of the gate structure 290 adjacent to the ninth opening 505, and a dry etching process using the fourth etching mask 501 may be performed to partially remove the upper portion of the gate structure 290, thus an upper portion of the ninth opening 505 may be horizontally expanded.

Referring back to FIG. 28, processes that are substantially the same as or similar to the processes illustrated with reference to FIGS. 19 to 22 and 1 to 4 may be performed, and the semiconductor device may be manufactured.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
active patterns on a substrate, wherein each of the active patterns extend in a first direction substantially parallel to an upper surface of the substrate, and an isolation pattern is on at least a portion of respective sidewalls of each of the active patterns;
a gate structure on the active patterns and on the isolation pattern, wherein the gate structure extends in a second direction substantially parallel to the upper surface of the substrate and intersects the first direction;
a mask pattern on the gate structure, wherein a sidewall of the mask pattern is aligned with a sidewall of the gate structure; and
a division pattern on the isolation pattern, wherein the division pattern is in contact with the sidewall of the gate structure and the sidewall of the mask pattern.

2. The semiconductor device according to claim 1, further comprising:
a plurality of channels spaced apart from each other in a third direction perpendicular to the upper surface of the substrate,
wherein the gate structure is on an upper surface, a lower surface, and a sidewall of each of the plurality of channels.

3. The semiconductor device according to claim 2, wherein a width in the second direction of the mask pattern is greater than a width in the second direction of each of the channels.

4. The semiconductor device according to claim 2, wherein a portion of the gate structure on an uppermost channel among the plurality of channels, a portion of the gate structure between neighboring ones of the plurality of channels, and a portion of the gate structure below a lowermost channel among the plurality of channels have substantially same thickness in the third direction.

5. The semiconductor device according to claim 2, wherein a portion of the gate structure on an uppermost channel among the plurality of channels has a thickness in the third direction greater than a thickness of a portion of the gate structure between neighboring ones of the plurality of channels, and a thickness of a portion of the gate structure below a lowermost channel in the third direction among the plurality of channels.

6. The semiconductor device according to claim 2, wherein the mask pattern has a thickness in the third direction greater than a thickness in the third direction of each of the plurality of channels.

7. The semiconductor device according to claim 1, wherein the division pattern has a lower surface that is closer to the substrate than an upper surface of the isolation pattern.

8. The semiconductor device according to claim 1, wherein a length in a third direction of an upper surface of the division pattern is substantially same as a length in the third direction of an upper surface of the mask pattern with respect to the substrate, wherein the third direction is perpendicular to the upper surface of the substrate.

9. The semiconductor device according to claim 1, wherein the gate structure comprises a gate insulation pattern, a gate barrier pattern and a gate electrode, and
wherein the gate insulation pattern comprises a high-k dielectric material, and the gate barrier pattern comprises a metal nitride.

10. The semiconductor device according to claim 9, the mask pattern is in contact with a sidewall of the gate electrode in the second direction.

11. The semiconductor device according to claim 1, wherein the mask pattern comprises silicon nitride.

12. The semiconductor device according to claim 1, further comprising:
a source/drain layer on a portion of each of the active patterns; and
a contact plug on the source/drain layer.

13. A semiconductor device comprising:
active patterns on a substrate, each of the active patterns extending in a first direction substantially parallel to an upper surface of the substrate, and an isolation pattern is on at least a portion of respective sidewalls of each of the active patterns;
a gate structure on the active patterns and on the isolation pattern, wherein the gate structure extends in a second direction substantially parallel to the upper surface of the substrate and intersects the first direction;
a division pattern comprising:
a lower portion that is in contact with an end portion of the gate structure; and
an upper portion on the lower portion and in contact with the lower portion, the upper portion having a width in the second direction greater than a width in the second direction of the lower portion; and
a mask pattern on the gate structure, the mask pattern in contact with a sidewall of the upper portion of the division pattern,
wherein a lower surface of the upper portion of the division pattern has a length substantially same as a length of a lower surface of the mask pattern with respect to the substrate.

14. The semiconductor device according to claim 13, further comprising:
a plurality of channels spaced apart from each other on the substrate in a third direction substantially perpendicular to the upper surface of the substrate,
wherein the gate structure is on an upper surface, a lower surface, and a sidewall of the plurality of channels.

15. The semiconductor device according to claim 14, wherein the mask pattern has a width in the second direction greater than a width in the second direction of each of the plurality of channels.

16. The semiconductor device according to claim 13, wherein a length in a third direction substantially perpendicular to the upper surface of the substrate of a lower surface of the lower portion of the division pattern is less than a length in the third direction of an upper surface of the isolation pattern with respect to the substrate.

17. The semiconductor device according to claim 13, wherein the gate structure comprises a gate insulation pattern, a gate barrier pattern and a gate electrode, and
wherein a sidewall of the lower portion of the division pattern contacts the gate barrier pattern.

18. A semiconductor device comprising:
active patterns on a substrate, each of the active patterns extending in a first direction substantially parallel to an upper surface of the substrate, and an isolation pattern is on at least a portion of respective sidewalls of each of the active patterns;
a gate structure on the active patterns and on the isolation pattern, wherein the gate structure extends in a second direction substantially parallel to the upper surface of the substrate and intersects the first direction;
a plurality of channels spaced apart from each other on the substrate in a third direction substantially perpendicular to the upper surface of the substrate, wherein each of the plurality of channels extend in the first direction;
a mask pattern on a portion of an upper surface of the gate structure;
a division pattern on the isolation pattern and extending into the gate structure and the mask pattern, wherein the division pattern is in contact with a sidewall of the mask pattern and a sidewall of the gate structure;
a source/drain layer on each of the active patterns; and
first and second contact plugs on the source/drain layer and the gate structure, respectively,
wherein the sidewall of the mask pattern and the sidewall of the gate structure align with each other.

19. The semiconductor device according to claim 18, wherein the division pattern extends into a portion of the gate structure and a portion of the mask pattern, which are between ones of the plurality of channels neighboring in the second direction.

20. The semiconductor device according to claim 18, wherein a length in the third direction of an upper surface of the division pattern is substantially same as a length in the third direction of an upper surface of the mask pattern with respect to the substrate.
